(19) United States
(12) Patent Application Publication
(10) Pub. No.: US 2009/0138784 A1
(43) Pub. Date: May 28, 2009

(54) CODING DEVICE AND CODING METHOD

(75) Inventors: Hiroki Tamura, Fukuoka (JP); Kazumi Doi, Fukuoka (JP); Yoshiya Ohsaki, Fukuoka (JP); Jun Endoh, Fukuoka (JP); Kanna Hara, Fukuoka (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/269,885

(22) Filed: Nov. 13, 2008

(30) Foreign Application Priority Data
Nov. 13, 2007 (JP) 2007-294890

(51) Int. Cl. H03M 13/05; G06F 11/10

(52) U.S. Cl. 714/776; 714/E11.032

(57) ABSTRACT

A coding method to code original data and transmit the coded data as a plurality of data packets to a destination, the coding method comprising: receiving packet loss information associated with the transmission of at least some of the plurality of data packets, the packet loss information including a lost packet restoration rate, a continuous packet loss rate and a packet loss rate of the packets transmitted to the decoding device; and generating an error-correcting redundant packet and inserting the error-correcting redundant packet in subsequent ones of the plurality of data packets for transmission to the destination based on the received packet loss information.

### CROSS-REFERENCE TO RELATED APPLICATIONS

This application is based upon and claims the benefit of priority of the prior Japanese Application No. 2007-294890, filed on Nov. 13, 2007, the entire contents of which are incorporated herein by reference.

### BACKGROUND

1. Field

The invention relates to a coding method and a coding device for transmitting a bit string of coded data as a packet to a decoding device, which is employed to generate original data by decoding compression-coded video and audio data.

2. Description of the Related Art

Conventionally, as shown in FIG. 13, a system for monitoring a remote place in real time is generally used, in which an image or video picked up by a camera and audio picked up by a microphone installed at a place to be monitored are transduced into electrical signals and forwarded to a MPEG (Moving Picture Experts Group) coding device, which further codes the received signals into a compression-coded bit string for transmission as an IP (Internet Protocol) packet to a MPEG decoding device through the Internet. Once the UDP packet is decoded by the MPEP decoding device, it is reproduced by a monitor and a speaker as video and audio, respectively.

In such a system, TCP (Transmission Control Protocol) or UDP (User Datagram Protocol) is normally used for transfer of IP packets. In a real-time transmission system, UDP is typically used since the reduction of delay time is given priority over the transport factor.

In an IP network (in particular, the Internet), a packet is transmitted from a transmission terminal to a receiving terminal through a number of repeaters of different performances, and the transmission band is varied among the repeaters. Hence, packets may be discarded or lost during transmission due to traffic of the repeater network, buffer overflows in the repeaters, and/or physical or electrical data error. To reduce such packet losses, a retransmission process, such as an ARQ (Automatic Repeat reQuest) scheme, with a limited number of transmission sessions in an upper layer or a method, such as an FEC (Forward Error Correction) scheme, for constantly transmitting a redundant packet to restore the lost packet is used.

According to the ARQ scheme, the receiving terminal responds to the transmitting terminal with an ACK (ACKnowledgement) signal when packets are received without any error; and with a NAK (Negative ACKnowledgement) signal upon detection of an error. Then, the transmission terminal that received the NAK signal retransmits a packet in place of the lost packet. Accordingly, the packet is retransmitted when lost, and therefore, the packet retransmission poses the problem of a delay time.

To avoid introducing a communication delay time, the FEC scheme may be used in place of the ARQ scheme. With the FEC scheme, a FEC packet for restoring the lost packet is transmitted in substantially the same manner as a coded packet. The FEC scheme is explained in detail with reference to FIG. 14, which illustrates a conceptual diagram showing an example in which one FEC packet is always transmitted for every ten IP packets (e.g., packets of video and audio that are to be transmitted). In this example, XOR (exclusive-OR) is calculated for each bit of the ten IP packets to generate the FEC packet.

For example, the bit string of the first packet is “1,1,1,0,0,0, . . . ”, and the bit string of the second packet is “1,0,1,1,0,1, . . . ” as shown in FIG. 14. The XOR “0” of the first bit “1” of the first packet and the first bit “1” of the second packet is used as the first bit of the FEC packet. In similar fashion, the second and subsequent bits are calculated thereby to produce the FEC packet for the first and second packets. Further, this FEC packet and the third packet are similarly calculated to produce the next FEC packet. This process is repeated up to the tenth packet to thereby produce one FEC packet for ten IP packets.

The receiving terminal receives ten IP packets and one FEC packet. Using the information indicating the order of the IP packets (for example, the sequence number in the RTP header), the packets are rearranged and the presence or absence of a lost packet is recognized. In the case where only one of the ten packets is lost, for example, the lost packet may be restored by performing the XOR operation on the remaining nine IP packets and the FEC packet.

As described above, in order to restore the lost IP packet, the FEC packet is required to be accurately transmitted to the receiving end, and for this purpose, various methods of generating and transmitting the FEC packet are known. “A method of inserting an FEC packet at regular time intervals” shown in FIG. 15, “a method of generating an FEC packet at regular time intervals and transmitting the FEC packet alternately from two FEC packet groups” shown in FIG. 16 and “a two-dimensional FEC packet insertion method” shown in FIG. 17 are some examples.

Each method is explained in detail below. In “the method of inserting an FEC packet at regular time intervals” as shown in FIG. 15, one FEC packet is generated from four IP packets, for example, and one FEC packet is transmitted once every five times. In other words, one FEC packet is transmitted after transmitting every four IP packets. In this method, the frequency of inserting the FEC packet is low and therefore the total bit rate of the IP packets and the FEC packets may be low. However, continuous packet loss may not be saved (the loss of two or more packets in the plurality of IP packets used for generating one FEC packet cannot be restored).

In “the method of generating an FEC packet at regular time intervals and transmitting the FEC packet alternately from two FEC packet groups” as shown in FIG. 16, one FEC packet is similarly generated from four IP packets but the method for transmitting the FEC packet is different. For example, eight IP packets (M-1 to M-8) and two FEC packets (F(1.2.3.4) and F(5.6.7.8)) are transmitted alternately in the order of “M-1”; “M-3”; “F(1.2.3.4)”, “M-6”; “M-8”, “M-2”, “M-4”, “M-5”, “M-7” and “F(5.6.7.8).” In this method, because the frequency of inserting the FEC packet is low, the total bit rate of the IP packets and the FEC packets is also low. Therefore, although the resistance to the loss of continuous two packets is high, the delay is great due to the increase in buffer amount for decoding at the receiving end.

According to “the two-dimensional FEC packet insertion method”, on the other hand, as shown in FIG. 17, one FEC packet (F(1.2.3.4)) is generated from four packets “M-1” to “M-4”; and another FEC packet (F(1.5)) is generated from two packets “M-1” and “M-5.” After transmitting four IP packets, one FEC packet is transmitted, and the FEC packet “F(1.5)” generated from the two IP packets is transmitted at the substantially same time as the IP packet “M-1.” In this method, since the insertion frequency of the FEC packet is high, the total bit rate of the IP packets and the FEC packets is high (six FEC packets need to be transmitted to transmit eight IP packets). Thus, the amount of buffer operation for decoding at the receiving end is increased, and therefore, the delay is increased. Nevertheless, this method is highly resistant to continuous packet loss.

### SUMMARY

There are a number of issues with the conventional methods described above. In order to secure a constant transfer rate with consideration for the processing load and the situation of the network connecting the transmitting and receiving ends, it is desirable to appropriately select a method suitable for the situation and the processing load of the network and intervals at which an FEC packet is inserted in each method. Typically, in a real-time IP transmission of video and audio signals, a compressed stream is transmitted as RTP (real-time transport protocol) packets, and in order to adjust the transmission rate thereof, RTCP (RTP control protocol) packets are transmitted periodically from the stream receiving side (decoding device) to the stream transmission side (coder, coding device). An RR packet (receiver information) of the RTCP packets also contains the packet loss rate, and it is a common practice to change the transfer rate dynamically using this information at the stream transmission side to thereby secure the quality of the decoded image and audio (see, for example, Japanese Patent Application Laid-Open No. 4-160826).

The conventional techniques described above, however, pose a challenge to select an appropriate method of generating and inserting an FEC packet. For example, the RTCP packet contains no information such as the packet loss continuity required for selecting an FEC packet generation and insertion method, and no area is available for the user to describe his/her original information. Thus, it is difficult to select an appropriate method of generating and inserting an FEC packet.

Accordingly, described herein are methods and systems for providing a coding device wherein an appropriate method of generating and inserting an FEC packet may be selected in accordance with the network situation.

For example, in one embodiment of the present invention, there is provided a coding method to code original data and transmit the coded data as a plurality of data packets to a destination, the coding method comprising: receiving packet loss information associated with the transmission of at least some of the plurality of data packets, the packet loss information includes a lost packet restoration rate, a continuous packet loss rate and a packet loss rate of the packets transmitted to the decoding device; and generating an error-correcting redundant packet and inserting the error-correcting redundant packet in subsequent ones of the plurality of data packets for transmission to the destination based on the received packet loss information.

It is to be understood that both the foregoing general description and the following detailed description are exemplary and explanatory only and are not restrictive of the invention, as claimed.

### BRIEF DESCRIPTION OF THE DRAWINGS

Embodiments are illustrated by way of example and not limited by the following figure(s).

FIG. 1 illustrates a general configuration of a system including a decoding device according to an example embodiment of the present invention;

FIG. 2 illustrates a configuration of a coding device according to an example embodiment of the present invention;

FIG. 3 illustrates an example of the information stored in a coded information DB (DataBase) according to an example embodiment of the present invention;

FIG. 4 illustrates a configuration of a decoding device according to an example embodiment of the present invention;

FIG. 5 illustrates a packet transmission method determining process in a coding device according to an example embodiment of the present invention;

FIG. 6 illustrates an example of determining an FEC packet generation and insertion method based on the degree of effect according to an example embodiment of the present invention;

FIG. 7 illustrates a configuration of a coding device according to an example embodiment of the present invention;

FIG. 8 illustrates an example of the information stored in a coded information DB according to an example embodiment of the present invention;

FIG. 9 is a diagram showing an example of the information stored in a schedule DB according to an example embodiment of the present invention;

FIG. 10 illustrates an example of the information stored in a schedule DB including a priority schedule according to an example embodiment of the present invention;

FIG. 11 illustrates a video distribution system having a learning result recording server arranged on the network according to an example embodiment of the present invention;

FIG. 12 illustrates an example of the computer system for executing the coding program according to an example embodiment of the present invention;

FIG. 13 illustrates a related-art system for monitoring a remote place in real time in a;

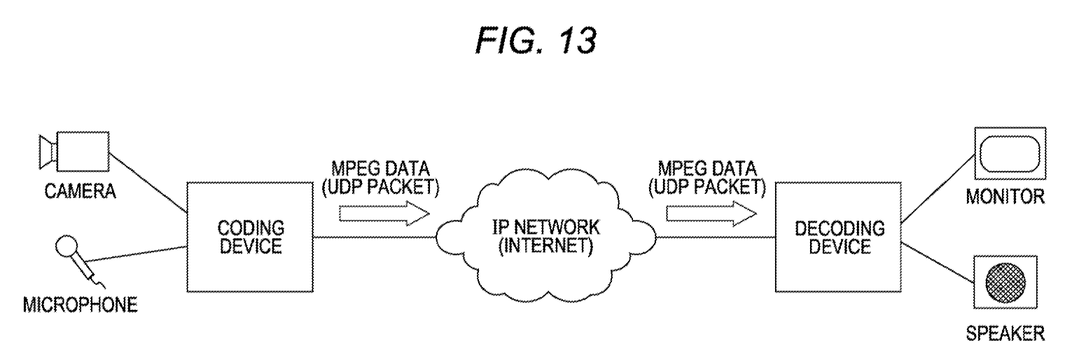

FIG. 14 illustrates a related-art example of always transmitting one FEC packet for every ten IP packets;

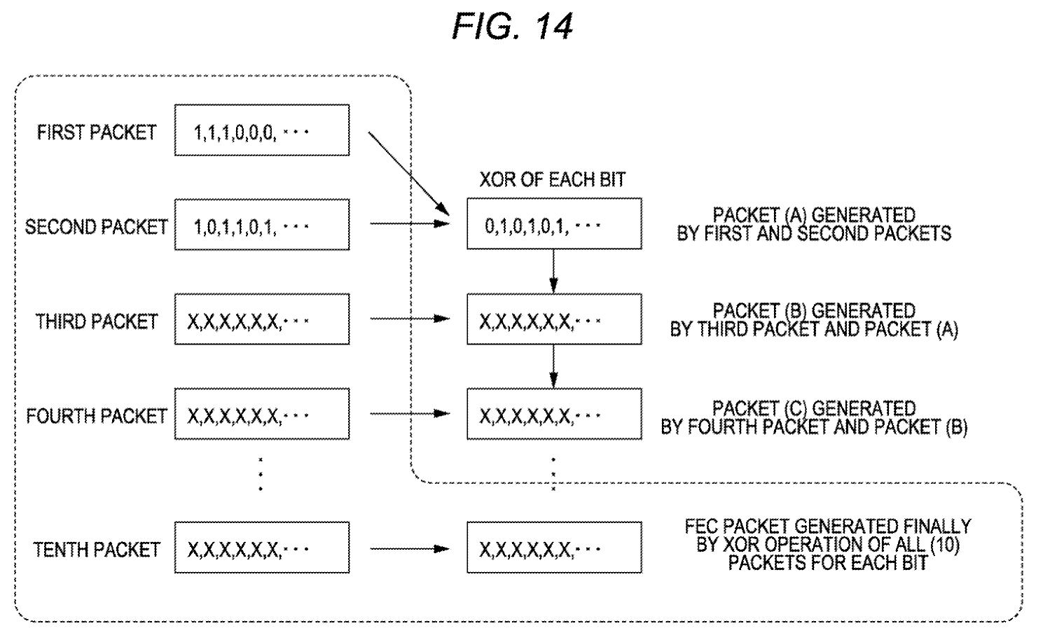

FIG. 15 illustrates a related-art method of inserting an FEC packet at regular time intervals;

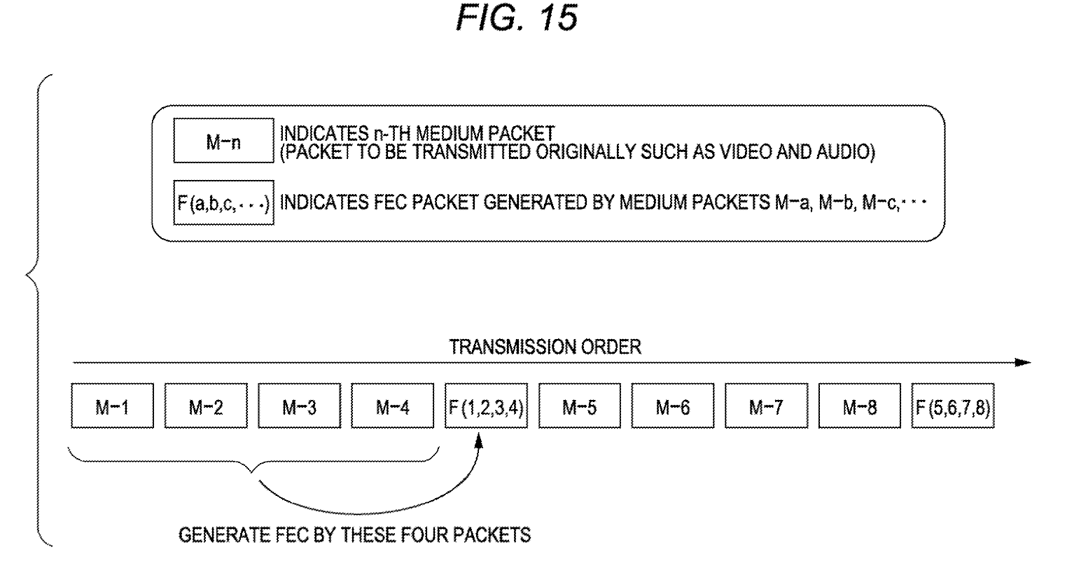

FIG. 16 illustrates a related-art method of transmitting an FEC packet alternately from two FEC packet groups generated at regular time intervals; and

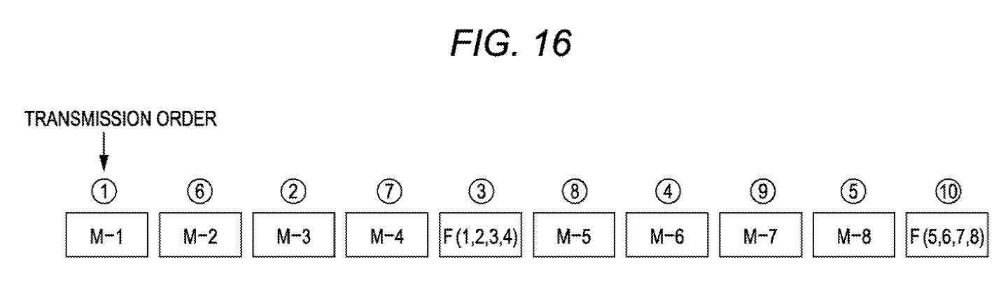

FIG. 17 illustrates a related-art two-dimensional FEC packet insertion method.

### DETAILED DESCRIPTION OF EXAMPLE EMBODIMENTS

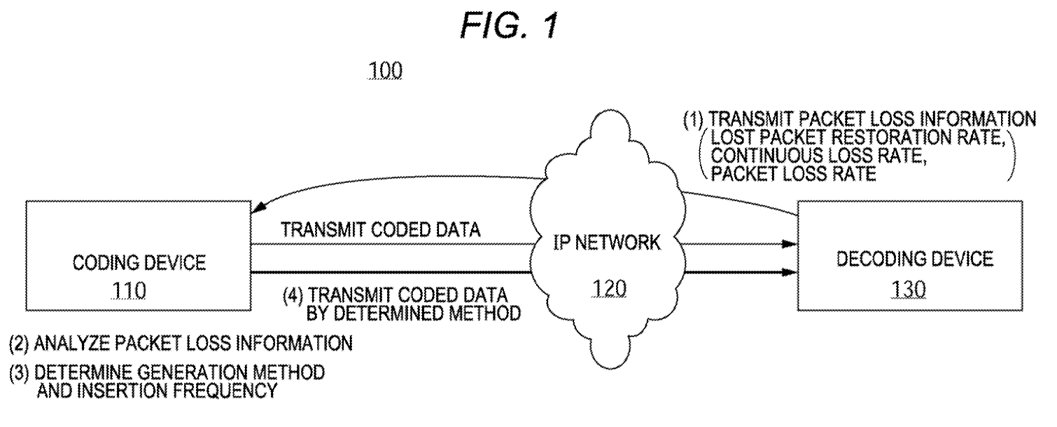

FIG. 1 illustrates a general configuration of a system 100 including a coding device and a decoding device according to an embodiment. As shown, the system 100 includes a coding device 110 for transmitting a bit string of compression-coded video and audio data as a packet and a decoding device 130 for generating original data by decoding the received coded data, connected to each other through a data network 120, which may be an IP network such as the Internet, an intranet, or any other public or private data network.

The coding device 110 shown here, for example, is a MPEG coding device for retrieving image and audio from a camera and a microphone, respectively, installed at a place to be monitored and transmitting a compression-coded bit string as a UDP packet to the decoding device 130 through the Internet 120. In this system, a remote place is monitored in real time by decoding the data and reproducing the decoded data through a monitor and a speaker at the side of the decoding device 130.

In this configuration, the coding device 110 is connected to or otherwise in communication with a decoding device 130 through a network 120. The decoding device 130 is configured to generate original data by decoding the compression-coded video and audio data from bit strings of coded data that are transmitted to the decoding device as data packets, such as IP packets. Then, an appropriate FEC packet generation and insertion method may be selected in accordance with the network situation.

The coding device 110 is to transmit a bit string of the compression-coded video and audio data as data packets, such as IP packets, to the decoding device 130, which in turn transmits the packet loss information including the lost packet restoration rate, the continuous packet loss rate and the packet loss rate of the transmitted packets as a UDP packet to the coding device 110 (see (1) of FIG. 1).

For example, the coding device 110 transmits a bit string of compression-coded video and audio data as a packet to the decoding device 130 using “the method of inserting an FEC packet at regular time intervals”, “the method of generating an FEC packet at regular intervals and transmitting the FEC packet alternately from two FEC packet groups” or “the two-dimensional FEC packet insertion method” as described above. The decoding device 130 then generates the packet loss information by calculating the lost packet restoration rate, the continuous packet loss rate and the packet loss rate of the packets received from the coding device during a predetermined length of time, and transmits the generated packet loss information to the coding device as a UDP packet.

Then, in order to restore the lost packets based on the packet loss information received from the decoding device 130, the coding device 110 determines in real time the method of generating and inserting an FEC packet that serves as an error-correcting redundant packet to be inserted periodically, generates the FEC packet based on the determined error-correcting redundant packet generation and insertion method, and transmits the coded data to the decoding device 130 (see (2) to (4) of FIG. 1).

In one example, the coding device 110 analyzes the packet loss information received from the decoding device 130. Then, in the case where “the total bit rate is high and no continuous packet loss occurs,” the coding device 110 may decide to use “the method of inserting an FEC packet at regular time intervals,” which is low in total bit rate. Consequently, the coding device 110 is to transmit subsequent IP packets using “the method of inserting the FEC packet at regular time intervals.”

In the case where “the total bit rate is high and the continuous packet loss slightly occurs”, the coding device 110 may decide to use “the method of generating an FEC packet at regular intervals and transmitting the FEC packet alternately from two FEC packet groups,” which is low in total bit rate and resistant to the continuous packet loss. Consequently, the coding device 110 is to transmit subsequent IP packets using “the method of generating an FEC packet at regular intervals and transmitting the FEC packet alternately from two FEC packet groups.”

In the case where “the total bit rate is low and the continuous packet loss frequently occurs,” the coding device 110 may decide to use “the two-dimensional FEC packet insertion method,” which is higher in the total bit rate and resistant to the continuous packet loss. Consequently, the coding device 110 is to transmit subsequent IP packets using “the two-dimensional FEC packet insertion method.”

The coding device 110 may select any of the methods described above and further determine the intervals at which the FEC packets are inserted in each of methods and transmit the FEC packets at the determined insertion intervals. For example, the coding device 110 may change the currently used method and/or the FEC packet insertion interval based on the packet loss information received from the decoding device.

Accordingly, as described above, a coding device may be configured to receive packet loss information from a decoding device in real time and also grasp the load situation of the network. As a result, an appropriate FEC packet generation and insertion method may be selected in accordance with the network situation.

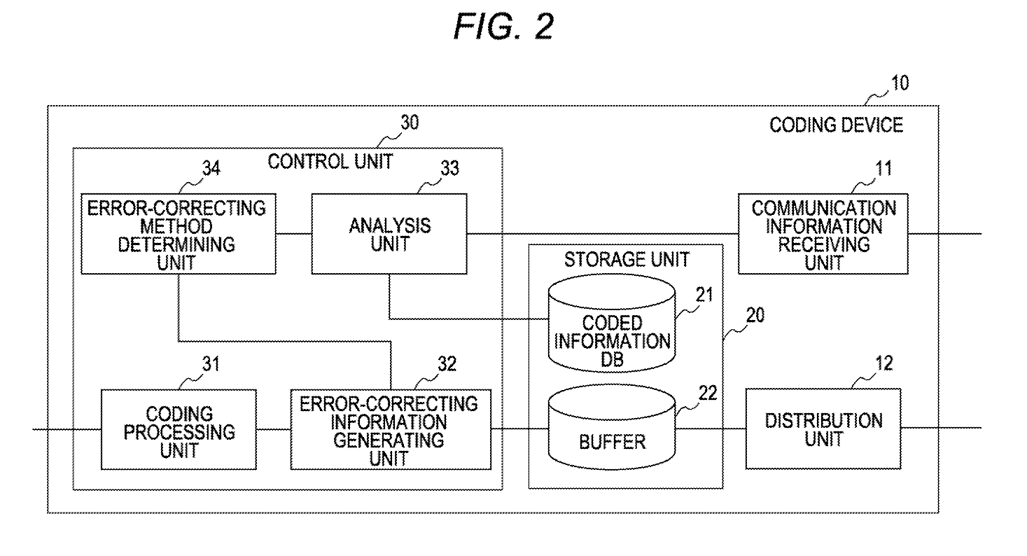

FIG. 2 illustrates a configuration of a coding device 10 according to an embodiment. The coding device 10 may be used in the system 100 (FIG. 1) as the coding device 110. The coding device 10 includes a communication information receiving unit 11, a distribution unit 12, a storage unit 20 and a control unit 30.

The communication information receiving unit 11 receives, from a decoding device, such as the decoding device 130 (FIG. 1), the packet loss information including the lost packet restoration rate, the continuous packet loss rate and the packet loss rate of the packets transmitted to the decoding device. With regard to the packets transmitted by the coding device 10, the decoding device may calculate the lost packet restoration rate, the continuous packet loss rate and the packet loss rate. Then, the communication information receiving unit 11 receives, through the IP network, the UDP packet constituting the packet loss information transmitted from the decoding device, and outputs the packet loss information to an analysis unit 33 that is included in the control unit 30 and described later.

The distribution unit 12 transmits a bit string of the compression-coded video and audio data as a packet to the decoding device. For example, the distribution unit 12 transmits, through the network to the decoding device, the IP packets (which are data packets) and the FEC packets generated from the coding processing unit 31 and the error-correcting information generating unit 32 described later.

The storage unit 20 stores data and programs required for various processes executed by the control unit 30. In particular, the storage unit 20 includes a coded information DB 21 and a buffer 22 as elements closely related to the invention.

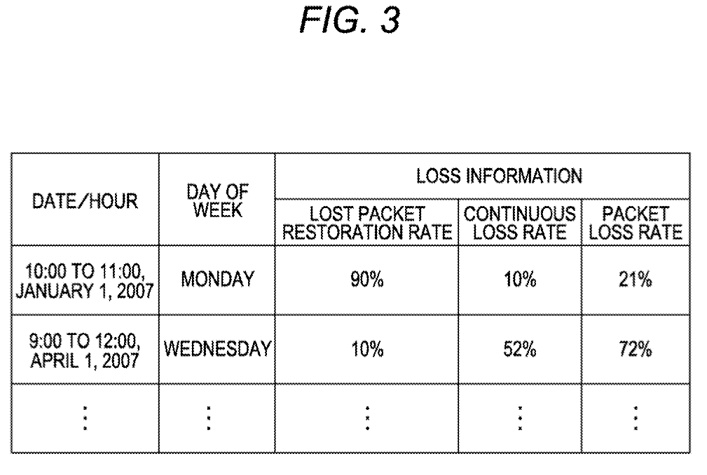

The coded information DB 21 stores the packet loss information received by the communication information receiving unit 11. FIG. 3 illustrates an example of the information stored in the coded information DB 21. As exemplified in FIG. 3, the coded information DB 21 stores “Jan. 1, 2007, 10:00 to 11:00, Monday; 90%; 10%; 21%” as “date/hour” to indicate when the packet loss information is received, “day of the week” to indicate when the packet loss information is received, “lost packet” to indicate the degree to which the lost packets have been restored, “continuous packet loss rate” to indicate the ratio in which the packets are continuously lost and “packet loss rate” to indicate the ratio in which the packets are lost, respectively.

The buffer 22 is a temporary area for temporarily storing the packets transmitted to the decoding device. For example, a bit string of the coded data generated by the coding processing unit 31 as described later is temporarily stored as a packet and the FEC packet generated by the error-correcting information generating unit 32 is temporarily stored in the buffer 22.

The control unit 30 has an internal memory for storing control programs such as an OS (operating system), required data and programs defining various processing operations. The control unit 30 also includes a coding processing unit 31, an error-correcting information generating unit 32, an analysis unit 33 and an error-correcting method determining unit 34 to execute various processes.

The coding processing unit 31 generates the compression-coded video and audio data. For example, the coding processing unit 31 receives the video and audio data input from an external source, compression-codes the received video and audio data, and outputs a bit string of the coded data as a packet to the error-correcting information generating unit 32 described later and the buffer 22.

The error-correcting information generating unit 32 generates an FEC packet that serves as an error-correcting redundant packet based on the error-correcting redundant packet generation and insertion method determined by the error-correcting method determining unit 34 as described later, and inserts the FEC packet into the packets transmitted to the decoding device. For example, the error-correcting information generating unit 32 generates an FEC packet based on the error-correcting redundant packet generation and insertion method determined by the error-correcting method determining unit 34, and inserts the FEC packet in the IP packets input by the coding processing unit 31 based on the insertion method determined by the error-correcting method determining unit 34. The error-correcting information generating unit 32 inputs the IP packets input by the coding processing unit 31 and the inserted FEC packets to the buffer 22.

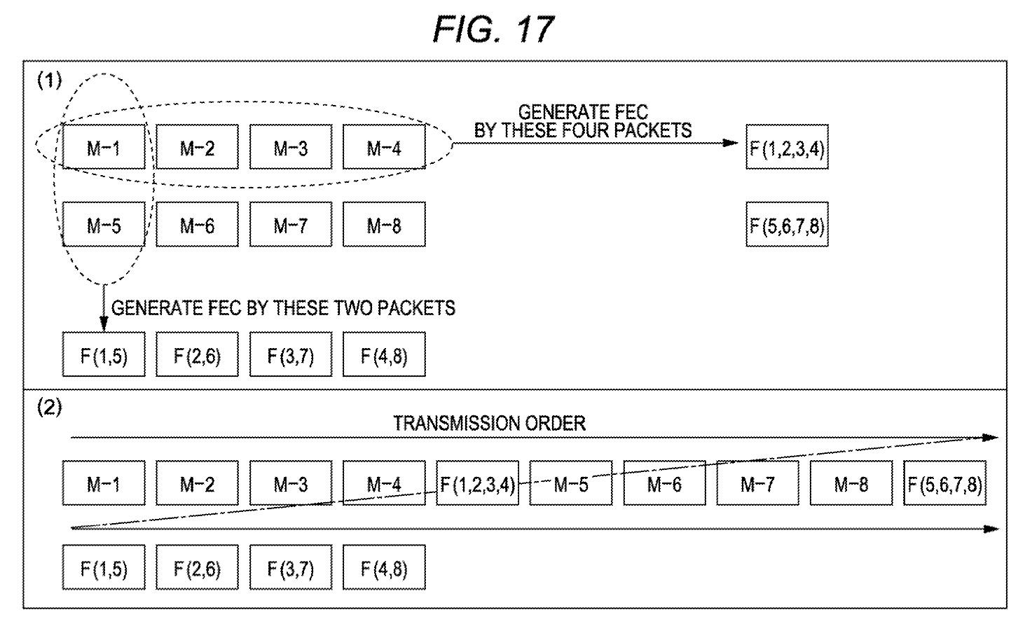

Upon receipt of the notification that the generating method of “the method of inserting an FEC packet at regular time intervals” and the insertion method of “2 packets” are determined by the error-correcting method determining unit 34, for example, the error-correcting information generating unit 32 generates an FEC packet from two IP packets input by the coding processing unit 31. The FEC packet thus generated is inserted following the two IP packets and output to the buffer 22. Upon receipt of the notification that the generating method of “the two-dimensional FEC packet insertion method” and the insertion method of “4 packets, 2 packets” are determined by the error-correcting method determination 34, for example, the error-correcting information generating unit 32 generates an FEC packet two-dimensionally by treating four IP packets input by the coding processing unit 31 as a group while at substantially the same time inserting the FEC packet two-dimensionally (FIG. 17) in the IP packets and outputs the packets to the buffer 22.

The analysis unit 33 analyzes the packet loss information received by the communication information receiving unit 11, and stores the analysis result in the coded information DB 21. For example, the analysis unit 33 acquires “the lost packet restoration rate” “the continuous packet loss rate” and “the packet loss rate” from the packet loss information received by the communication information receiving unit 11, while at substantially the same time acquiring the date/hour and the day of the week on which the particular packet loss information is received. These information are associated with each other and stored in the coded information DB 21.

The error-correcting method determining unit 34 determines the error-correcting redundant packet generation and insertion method for periodically inserting an error-correcting redundant packet to restore the packet loss based on the packet loss information received by the communication information receiving unit 11. For example, the error-correcting method determining unit 34 determines the method of generating and inserting an FEC packet that serves as an error-correcting redundant packet inserted periodically to restore the lost packet by referring to the coded information DB 21 storing the packet loss information analyzed by the analysis unit 33, and outputs the determined result to the error-correcting information generating unit 32.

In the case where the packet loss information stored in the coded information DB 21 is “high in lost packet restoration rate and low in both continuous packet loss rate and packet loss rate,” for example, the error-correcting method determining unit 34 outputs a command to employ “the method of inserting an FEC packet at regular time intervals” and to “lengthen the insertion interval” to the error-correcting information generating unit 32. In the case where the packet loss information stored in the coded information DB 21 is “low in lost packet restoration rate and high in both continuous packet loss rate and packet loss rate”, for example, the error-correcting method determining unit 34 outputs a command to employ “the method of generating an FEC packet at regular intervals and transmitting the FEC packet alternately from two FEC packet groups” or “the two-dimensional FEC packet insertion method” and to “shorten the insertion interval” to the error-correcting information generating unit 32.

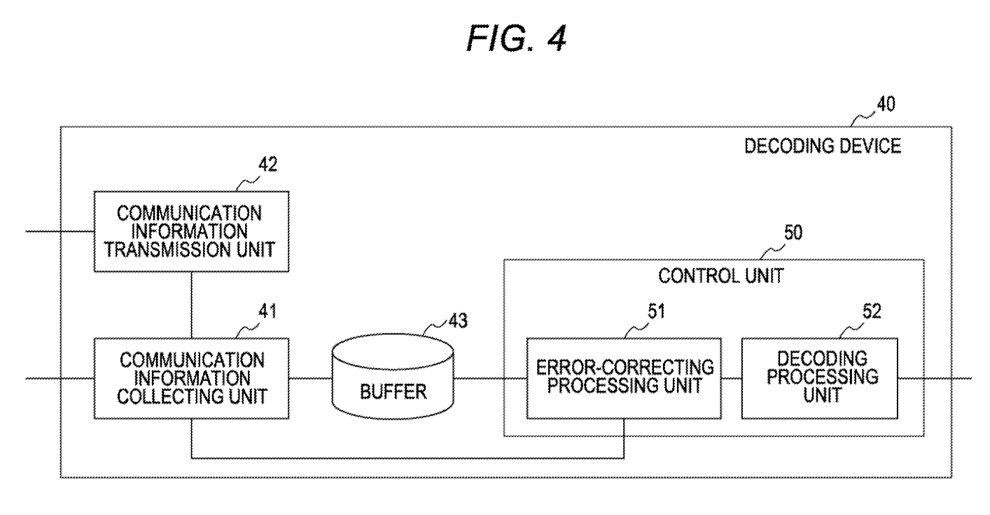

FIG. 4 illustrates a configuration of a decoding device 40 according to an embodiment. The decoding device 40 may be employed as the decoding device 130 in FIG. 1. The decoding device 40 includes a communication information collecting unit 41, a communication information transmission unit 42, a buffer 43 and a control unit 50.

The communication information collecting unit 41 receives the IP packets and the FEC packets transmitted from the coding device 10, via the IP network 120 (FIG. 1). For example, the communication information collecting unit 41, upon receipt of the IP packets transmitted from the coding device 10, stores the IP packets in the buffer 43. In the process, the communication information collecting unit 41 analyzes the RTP header of the received IP packet and confirms the continuity of the sequence numbers to check for the packet loss. In the absence of a packet loss, the communication information collecting unit 41 discards the FEC packet to be used for the IP packet loss. On the other hand, in the presence of an IP packet loss, the FEC packet to be used for the media packet loss is stored in the buffer 43 together with the IP packet.

Further, the communication information collecting unit 41 calculates the packet loss information including the lost packet restoration rate indicating the degree to which the lost packets may be restored, the packet loss rate per second (indicating the percentage of the lost packets in all the IP packets received) and the continuous loss rate (indicating the percentage of the number of times two continuous packets are lost in the total number of times the packets are lost). The calculation result is stored in a memory or the like (not shown in FIG. 4).

The communication information transmission unit 42 transmits the packet loss information to the coding device 10. For example, the communication information transmission unit 42 periodically reads the packet loss information stored in the memory or the like, not shown, by the communication information collecting unit 41, and transmits the read packet loss information to the coding device 10 by including the read packet loss information in the payload of the UDP packet.

The buffer 43 temporarily stores the IP packets and the FEC packets received by the communication information collecting unit 41. Further, the buffer 43, outputs the IP packets and the FEC packets stored by the communication information collecting unit 41 to the error-correcting processing unit 51 in accordance with the read command received from the error-correcting processing unit 51 described later.

The control unit 50 has an internal memory for storing control programs such as an OS (operating system), programs defining various processing operations and required data, and further has the error-correcting processing unit 51 and a decoding processing unit 52 to execute various processes, as elements closely related to the invention.

In the case where a packet transmitted by the coding device 10 is lost, the error-correction processing unit 51 restores the lost packet. For example, the error-correcting processing unit 51 acquires the packet stored in the buffer 43. In the case where the acquired packet is a IP packet, the error-correcting processing unit 51 transmits the acquired IP packet to the decoding processing unit 52. In the case where the acquired packet is an FEC packet, on the other hand, the error-correction processing unit 51 restores the lost IP packet from the IP packets in the same group as the FEC packet and transmits the restored packet to the decoding processing unit 52. In the process, the ratio of the number of the packets restored to the number of the lost IP packets is calculated for each second, and transmitted as the lost packet restoration rate to the communication information collecting unit 41.

The decoding processing unit 52 generates original data by restoring the packet transmitted from the coding device 10. For example, the decoding processing unit 52 receives the IP packets and the restored IP packets from the error-correction processing unit 51 and generates the original data by restoring the received packets.

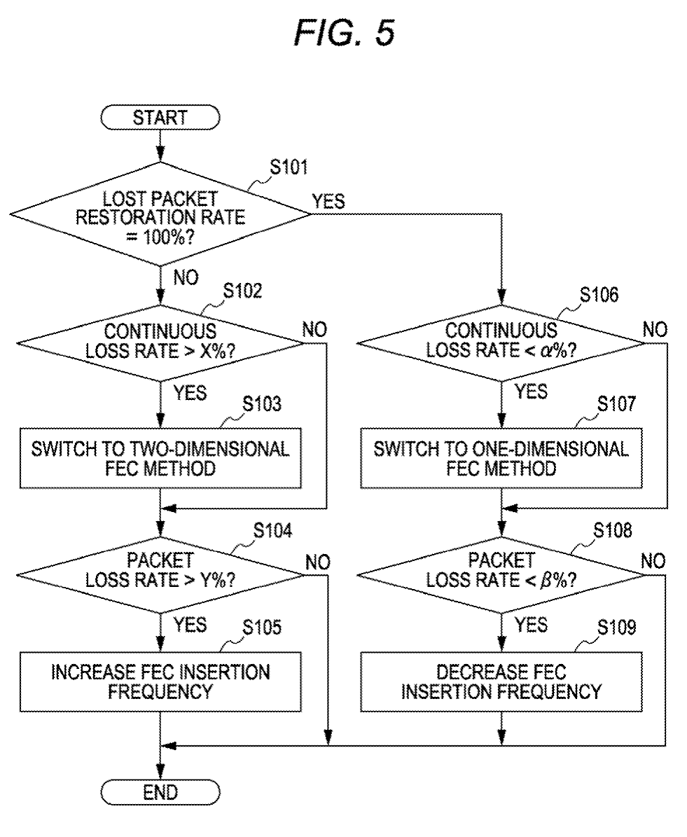

FIG. 5 illustrates a packet transmission method determining process in a coding device according to an embodiment. For illustrative purposes only and not to be limiting thereof, FIG. 5 is described with reference to the coding device 10 shown in FIG. 2 and the system 100 shown in FIG. 1.

As shown in FIG. 5, at S101, the error-correcting method determining unit 34 of a coding device, such as the coding device 10, determines whether the lost packet restoration rate is at 100%. As referred herein, whenever a set or predetermined value is provided, the provided value is at or substantially at such a value. For example, as noted above, there is a determination of whether the lost packet restoration rate is at 100%. Thus, such a determination includes a determination of whether the lost packet restoration rate is at 100% or substantially at 100%.

At S102, in the case where the lost packet restoration rate is not at substantially 100% (that is, less than 100%), the error-correcting method determining unit 34 further determines whether the continuous loss rate is larger than X % (a first predetermined threshold percentage value) by referring to the coded information DB 21.

At S103, in the case where the continuous loss rate is larger than X % the error-correcting method determining unit 34 determines the “two-dimensional FEC method” as the FEC packet generation and insertion method and, at S104, further determines whether the packet loss rate is larger than Y % (a second predetermined threshold percentage value) by referring to the coded information DB 21.

On the other hand, in the case where the continuous loss rate is equal to or smaller than X % (NO in step S102), the error-correcting method determining unit 34 proceeds to S104 to determine whether the packet loss rate is larger than Y % by referring to the coded information DB 21, thus bypassing the operation at S103.

At S105, in the case where the packet loss rate is larger than Y %, the error-correcting method determining unit 34 is to increase the FEC packet insertion frequency and notifies the determined insertion method and the insertion frequency to the error-correcting information generating unit 32.

On the other hand, in the case where the packet loss rate is equal to or smaller than Y % (NO in step S104), the error-correcting method determining unit 34 notifies the determined insertion method to the error-correcting information generating unit 32 without increasing the FEC packet insertion frequency.

At S106, returning to the beginning of the process illustrated in FIG. 5, in the case where the lost packet restoration rate is 100% (YES at S101), the error-correcting method determining unit 34 determines whether the continuous loss rate is smaller than α% (a third predetermined threshold percentage value).

At S107, in the case where the continuous loss rate is smaller than α%, which is the case where the continuous loss rate is sufficiently low, the error-correcting method determining unit 34 determines the “one-dimensional FEC method” as the FEC packet generation and insertion method.

At S108, the error-correcting method determining unit 34 further determines whether the packet loss rate is smaller than β% (a fourth predetermined threshold percentage value), to whether the packet loss rate is sufficiently low, by referring to the coded information DB 21.

On the other hand, in the case where the continuous loss rate is equal to or larger than α% (NO in step S106), the error-correcting method determining unit 34 proceeds to S108 to determine whether the packet loss rate is smaller than β% without switching to the “one-dimensional FEC method” at S107.

At S109, in the case where the packet loss rate is smaller than β%, the error-correcting method determining unit 34 is to decrease the FEC packet insertion frequency and notifies the determined insertion method and insertion frequency to the error-correcting information generating unit 32.

On the other hand, in the case where the packet loss rate is larger than β% (NO in step S108), the error-correcting method determining unit 34 notifies the determined insertion method to the error-correcting information generating unit 32 without decreasing the FEC packet insertion frequency.

Accordingly, the packet loss information including the lost packet restoration rate, the continuous packet loss rate and the packet loss rate of the packets transmitted to the decoding device is received by the coding device. Based on the received packet loss information, the method of generating and inserting an FEC packet, which is an error-correcting redundant packet periodically inserted to restore the lost packet, is determined. In turn, based on the determined method of generating and inserting the error-correcting redundant packet, an error-correcting redundant packet is generated and inserted in the packets transmitted to the decoding device. Thus, an appropriate FEC packet generating and insertion method may be selected in accordance with the network situation.

In another embodiment, a FEC packet generating and insertion method may be determined by taking into consideration the effect of the transmitted packet on the decoded data, in addition to the packet loss information received from the decoding device. In this embodiment, the coding processing unit 31 is to determine the degree of importance of the input data, and notifies the determination result to the error-correcting method determining unit 34. The error-correcting method determining unit 34 determines the FEC packet generating and insertion method from the notified importance degree and the packet loss information stored in the coded information DB and notifies the error-correcting information generating unit 32 of the determined method. The error-correcting information generating unit 32 thus notified generates and inserts the FEC packet based on the notified FEC packet generating and insertion method and stores the packets in the buffer 22. After that, the distribution unit 12 reads the packets from the buffer 22 for transmission to the decoding device 40.

In transmitting data coded by MPEG or H.26X techniques, for example, the data called I picture from which one still image may be obtained by decoding is first transmitted, followed by the transmission of the data called P picture and B picture which are obtained by compressing only the difference from the referred previous frame. Therefore, if the I picture is not correctly received and decoded in a decoding device, such as the decoding device 40 (stream receiving side), the subsequent decoding operation fails. In such a case, the received data is unavoidably discarded or the image is reproduced while frequently causing a decoding error until the next I picture is received. Further, a group composed of the I, P and B pictures is called a GOP (Group Of Picture) and assigned information called a GOP header required for GOP reproduction. In the case where a stream including the GOP header is lost, it may not be possible to decode the GOP, and the decode operation may not be resumed until the next GOP is received. On the other hand, in the case where the P or B picture is lost, the effect on the reproduced image is small due to the fact that the time until the next GOP head is received is short and by an error concealment function of the decoding device (a technique to make the image deterioration due to the decoding error less significant). In other words, the coding device 10 may specify at the time of coding whether a packet is to have a large effect or a small effect on the reproduced image in the decode operation of the video coded stream.

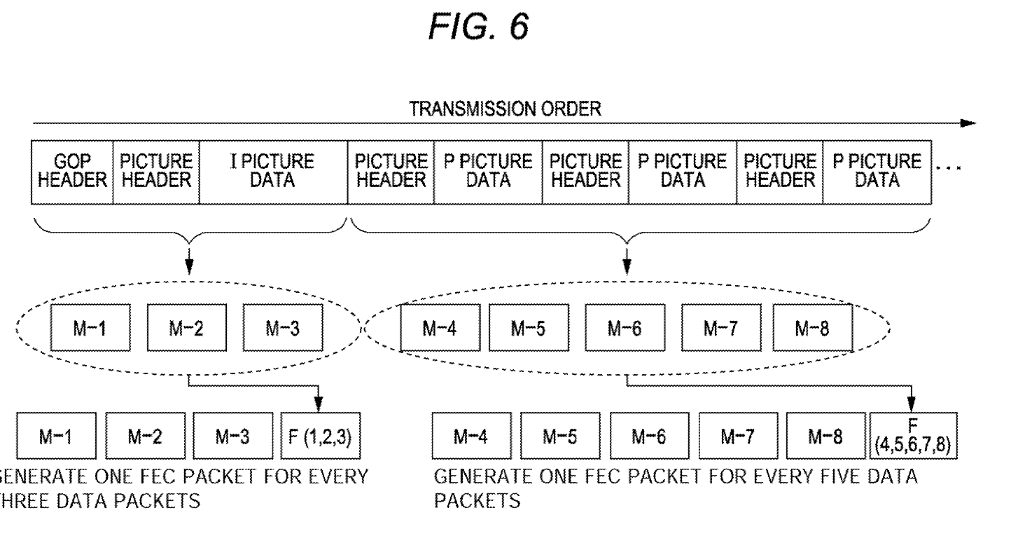

In view of the aforementioned data coding, FIG. 6 illustrates an example of determining the FEC packet generation and insertion method based on the degree of effect in accordance with one embodiment. As shown in FIG. 6, one FEC packet is generated, and inserted, from three packets “M-1” to “M-3” that include data having a large effect such as the GOP header or the I picture, while another FEC packet is generated, and inserted, from five packets “M-4” to “M-8” that do not include any data having a large effect. Accordingly, a FEC packet generation and insertion method may be determined or selected based on the degree of effect.

As described earlier, the degree of effect that a transmitted packet may have on the decoded image is calculated, and the FEC packet generation and insertion method is determined or selected based on the received packet loss information and the calculated degree of effect. Thus, the data restoration rate in the decoding device may be improved while at the same time an appropriate FEC packet generation and insertion method depending on the network situation may be selected.

The FEC generation frequency is increased with regard to the part such as the GOP header or the header or data of the I picture, the loss of which has a large effect, the FEC generation frequency is increased, while the FEC generation frequency is decreased for the part the loss of which has a smaller effect. In this way, the quality of the reproduced image can be maintained while suppressing the increase in the transmission rate of the stream as a whole.

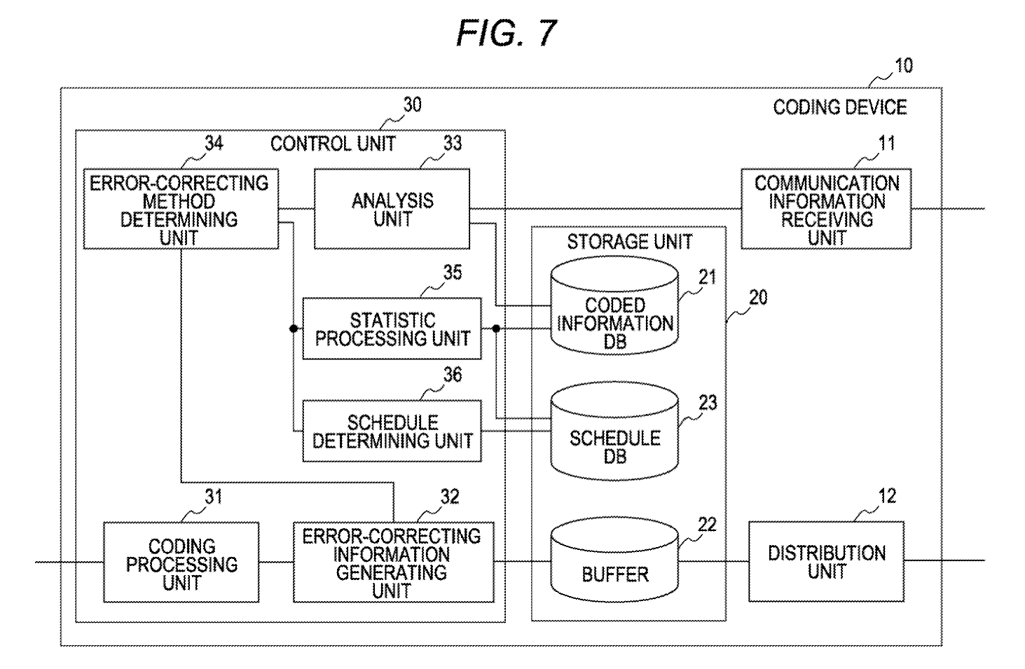

In another embodiment, a FEC packet generation and insertion method may be determined or selected by storing past statistical information of packet loss information and corresponding network load information, and taking such past information into consideration by comparing such past information with current packet loss information and corresponding network load information. FIG. 7 illustrates a configuration of a coding device according to this embodiment.

As shown in FIG. 7, the coding device 10 includes a communication information receiving unit 11, a distribution unit 12, a coded information DB 21, a buffer 22 and a schedule DB 23 of a storage unit 20, and a control unit 30 that includes a coding processing unit 31, an error-correcting information generating unit 32, an analysis unit 33, an error-correcting method determining unit 34, a statistic processing unit 35 and a schedule determining unit 36. The communication information receiving unit 11, the distribution unit 12, the buffer 22 of the storage unit 20, the coding processing unit 31, the error-correcting information generating unit 32 and the analysis unit 33 have similar functions to those of the communication information receiving unit 11, the distribution unit 12, the buffer 22 of the storage unit 20, the coding processing unit 31, the error-correcting information generating unit 32 and the analysis unit 33 of the control unit 30, respectively, of an embodiment shown in FIG. 2, and therefore, the detailed description thereof is not repeated. Here, a discussion is provided for the coded information DB 21 and the schedule DB 23 of the storage unit 20. Also, the error-correcting method determining unit 34, the statistic processing unit 35 and the schedule determining unit 36 of the control unit 30 are to have different functions from those of the first embodiment.

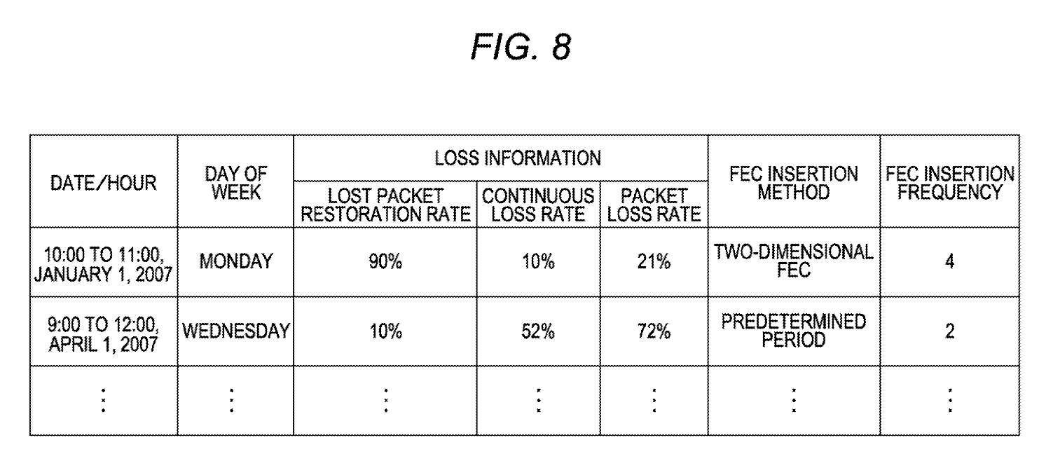

The coded information DB 21 of the storage unit 20 stores the received packet loss information and statistical information of this packet loss information in correspondence with the date/hour. As an example, the coded information DB 21 stores “Jan. 1, 2007, 10:00 to 11:00, Monday; 90%; 10%; 21%; two-dimensional FEC; 4” as shown in FIG. 8, as “date/hour” to indicate when the packet loss information is received, “day of the week” to indicate when the packet loss information is received, “lost packet restoration rate” to indicate the percentage of lost packets that have been restored, “continuous loss rate” to indicate the percentage of packets that have been continuously lost (that is, not restored), “packet loss rate” to indicate the percentage of packets that are lost, “FEC insertion method” to indicate the FEC insertion method used, and “FEC insertion frequency” to indicate the frequency at which the FEC packet in use is inserted, respectively. FIG. 8 illustrates an example of the information stored in the coded information DB.

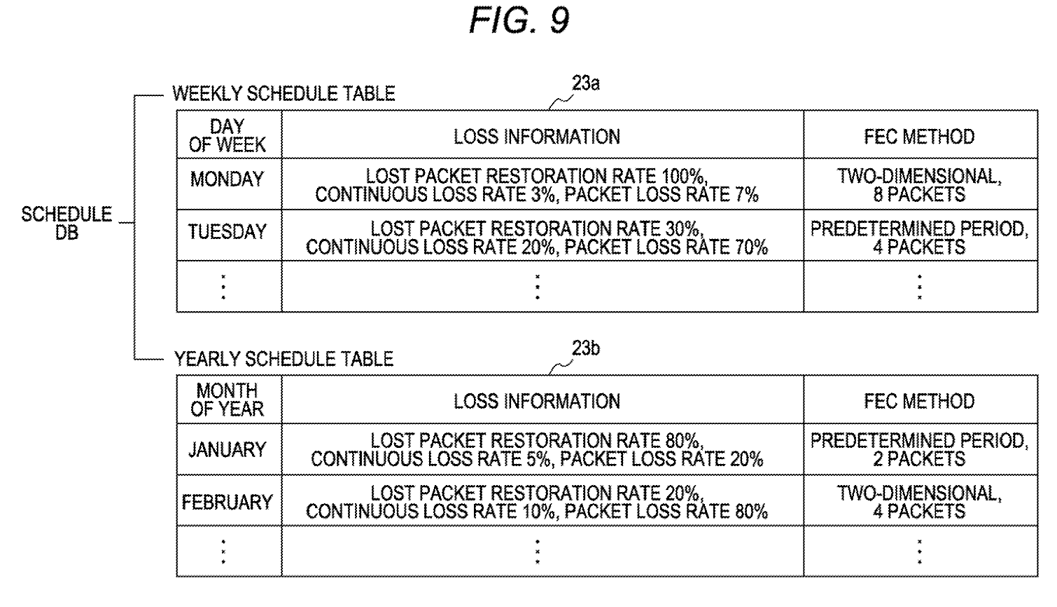

The schedule DB 23 stores the load information of the network. As an example, the schedule DB 23 includes a weekly schedule table 23a and a yearly schedule table 23b as shown in FIG. 9. FIG. 9 is a diagram showing an example of the information stored in the schedule DB 23.

The weekly schedule table 23a stores the load information of the network for one week. For example, the weekly schedule table 23a stores, in association with “day of the week” for each week, “loss information” and “FEC method” indicating the method and interval of FEC insertion selected for the day of the week. An example of the stored information is “Monday; lost packet restoration rate of 100%; continuous loss rate of 3%; packet loss rate of 7%; two-dimensional; 8 packets.”

The yearly schedule table 23b stores the load information of the network for one year. For example, the yearly schedule table 23b stores, in association with each “month” of the year, “loss information” and “FEC method” indicating the method and interval of FEC insertion selected for the month. An example of the stored information is “January; lost packet restoration rate of 80%; continuous loss rate of 5%; packet loss rate of 20%; regular interval; 2 packets.”

The error-correcting method determining unit 34 of the control unit 30 determines the generation and insertion method of the FEC packet providing an error-correcting redundant packet based on the packet loss information and the load information of the transmission date/hour held in the schedule DB 23. For example, the error-correcting method determining unit 34 determines a safe FEC generation method and FEC insertion interval with which the packet loss may be reduced or avoided and more lost packets may be restored between the FEC generation method and the FEC insertion interval notified by the schedule determining unit 36 (to be described later) and the FEC generation method and the FEC insertion interval currently used and notified from the statistical information processing unit 35. The FEC generation method and the FEC insertion interval thus determined are transmitted to the error-correcting information generating unit 32.

For example, the error-correcting method determining unit 34 is notified from the statistic processing unit 35 of the information “lost packet restoration rate of 90%; continuous loss rate of 10%; packet loss rate of 21%; two-dimensional FEC packet generation/insertion method; 4 packets” and from the schedule determining unit 36 of the information “packet restoration rate of 100%; continuous loss rate of 3%; packet loss rate of 7%; two-dimensional FEC packet generation/insertion method; 8 packets.” The error-correcting method determining unit 34 determines that the method notified from the schedule determining unit 36 which is “high in packet restoration rate and low in both continuous loss rate and packet loss rate” is safer, and transmits the determination “the two-dimensional FEC (generating method); 8 packets (insertion interval)” as the FEC generation and insertion method to the error-correcting information generating unit 32.

The statistic processing unit 35 collects statistics of the packet loss information for a predetermined time and the final FEC insertion method and frequency and stores the result in the schedule DB 23. For example, the statistic processing unit 35 calculates and detects the weekly and yearly packet statistical information and the used FEC generation and insertion method based on the packet loss information stored in the coded information DB 21 by the analysis unit 33 and the used FEC generation and insertion method and stores the calculation/detection results in the schedule DB 23. Then, the statistic processing unit 35 notifies the FEC generation method and the FEC insertion interval currently used to the error-correcting method determining unit 34.

The schedule determining unit 36 acquires the information on the date/hour and the day of the week corresponding to the current time from the weekly schedule table 23a and the yearly schedule table 23b stored in the schedule DB 23, and notifies a suitable FEC packet generation method and the suitable FEC packet insertion interval to the error-correcting method determining unit 34. If “Monday in January” is taken as an example, the weekly schedule table 23a stores “Monday; packet restoration rate of 100%; continuous loss rate of 3%; packet loss rate of 7%; two-dimensional; 8 packets” and the yearly schedule table 23b stores “January; lost packet restoration rate of 80%; continuous loss rate of 5%; packet loss rate of 20%; regular intervals; 2 packets.” The schedule determining unit 36 compares the stored data, determines that the method in the weekly schedule table 23a which is “high in packet restoration rate and low in continuous loss rate and packet loss rate” is safer, and notifies “packet restoration rate of 100%; continuous loss rate of 3%; packet loss rate of 7%; two-dimensional; 8 packets” to the error-correcting method determining unit 34 as the FEC generation method and the FEC insertion interval.

Accordingly, as described above, the statistical information of the packet loss information is held from the received packet loss information, and the FEC packet generation and insertion method is determined based on the received packet loss information and the held statistical information. Thus, a FEC packet generation and insertion method that may reduce or prevent the packet loss may be selected. Also, the network load information may be stored in association with the date/hour, and the FEC packet generation and insertion method may be determined based on the received packet loss information and the stored load information of the transmission date/hour. Thus, a high lost packet restoration rate may be maintained by changing the FEC generation method and insertion interval before the actual occurrence of a packet loss based on the past control record as well as by adjusting the current FEC generation method and insertion frequency.

Also, through quality learning by updating the stored statistical information with the latest information while continuing to adjust the FEC generation method and insertion frequency even during communication, data coding and decoding may be kept up with environmental changes such as improved network infrastructures. The quality learning may be performed by the statistic processing unit 35 or a separate quality learning unit (not shown) that may be connected to other components in the coding device 10 in a similar manner to the statistic processing unit 35.

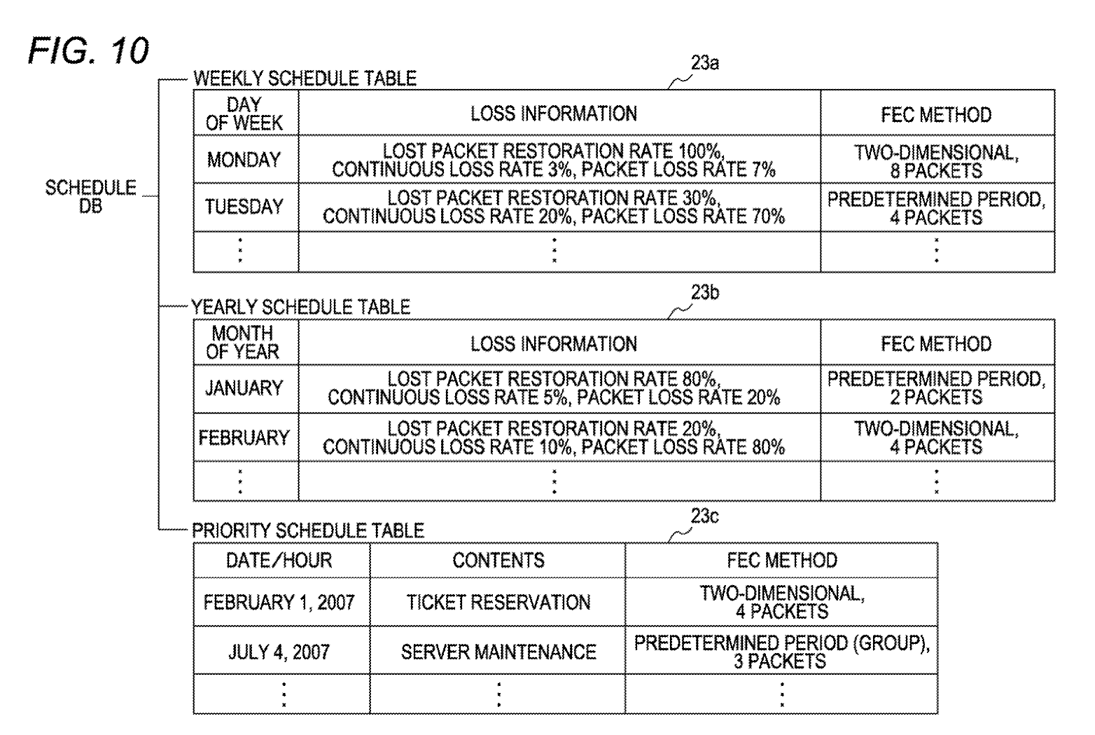

FIG. 10 illustrates an example of the information stored in the schedule DB including a priority schedule table 23c to be stored in the schedule DB 23. The priority schedule table stores priority information to be selected in priority to all the other information. That is, the schedule DB 23 may store a priority schedule table 23c in addition to the weekly schedule table 23a and the yearly schedule table 23b. The priority schedule table 23c stores, for example, “Feb. 1, 2007; ticket reservation; two-dimensional; 4 packets” as “date/hour” indicating the date/time of priority execution, “content” indicating the content of the process to be executed on the priority date and “FEC method” indicating the FEC generation and insertion method to be executed in priority, respectively.

The schedule determining unit 36 refers to the schedule DB 23 and, in the case where the priority schedule is stored, notifies the “FEC method” thereof with data indicating that it is a priority schedule to the error-correcting method determining unit 34. Then, the error-correcting method determining unit 34 determines the “FEC method” in accordance with the priority schedule notified by the schedule determining unit 36 without considering the FEC generation and insertion method notified from the statistic processing unit 35 and transmits the determined FEC method to the error-correcting information generating unit 32.

Accordingly, the FEC packet generation and insertion method may be changed in advance by informing in advance the date/hour when the network load becomes heavy, with the result that the network load can be reduced.

In yet another embodiment, by arranging a server device for recording the coded information (packet loss information) on the network and acquiring the past communication information at the server device when the coding device determines the FEC generation method and insertion interval, a similar effect may be obtained even in the absence of the learning result in the local device in such a case as when an additional coding device is provided.

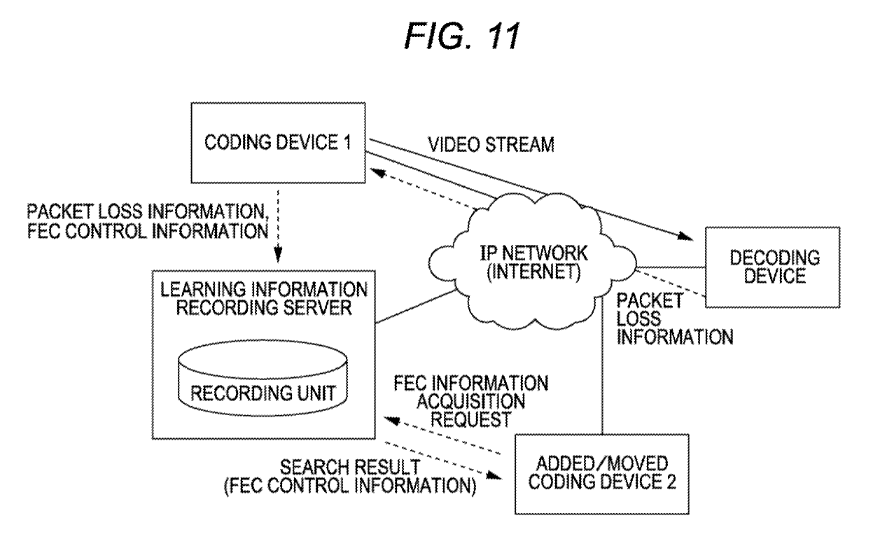

FIG. 11 illustrates a video distribution system in which a learning result recording server is arranged on the network according to an embodiment. The coding device provides a suitable FEC generation method and a suitable insertion frequency based on the past communication information and the current packet loss information as described earlier.

As shown in FIG. 11, the coding device 1 periodically records the control result (date/hour, address, optimized FEC generation method and insertion frequency) in the coded information DB and the schedule DB in itself. At the same time, the control result is transmitted to the server device at regular time intervals, and the server device records the control result received from the coding device in the recording unit of the server device. For example, the server device may hold the same packet loss information as the coding device 1. Based on this information, the server device may predict the FEC generation and insertion method corresponding to the date/hour.

In the case where a coding device 2 is newly added under this condition, there is no effective data in the coded information DB and the schedule DB in the coding device 2. Therefore, the coding device 2 transmits the date/hour and the address information (designation IP address) to the server device. Then, the server device searches the past data using the information received from the coding device 2 and returns to the coding device 2 the FEC insert information specified (predicted) to be currently suitable.

Accordingly, even the newly added coding device 2 may immediately optimize the FEC generation method and insertion frequency using the information received from the server device.

Additional embodiments are explained below with the forms classified according to (1) system configuration, etc. and (2) software program, respectively.

For system configuration, each component element of each device shown in the drawings is a functional concept, and does not necessarily have the shown physical configuration. In other words, specific forms of variance and integration of each device are not limited to those shown, and each device can be wholly or partly configured by functional or physical variance and integration (for example, the analysis unit 33 and the error-correcting method determining unit 34 may be integrated) in any unit according to the various load and operating conditions. Further, the whole or a part of each processing function of each device may be realized with a CPU and a program analyzed and executed by the CPU or as wired logic hardware. Further, the information including operations in a described process, specific names, various data and parameters described and shown in the above descriptions and drawings (such as FIGS. 3, 8, 9) may be changed unless otherwise specified.

For software programs, the various processes described in the embodiments above may be realized by executing a prepared program on a computer system such as a personal computer or a work station. The computer system for executing the program having the same function as the embodiments described above is explained as another embodiment below.

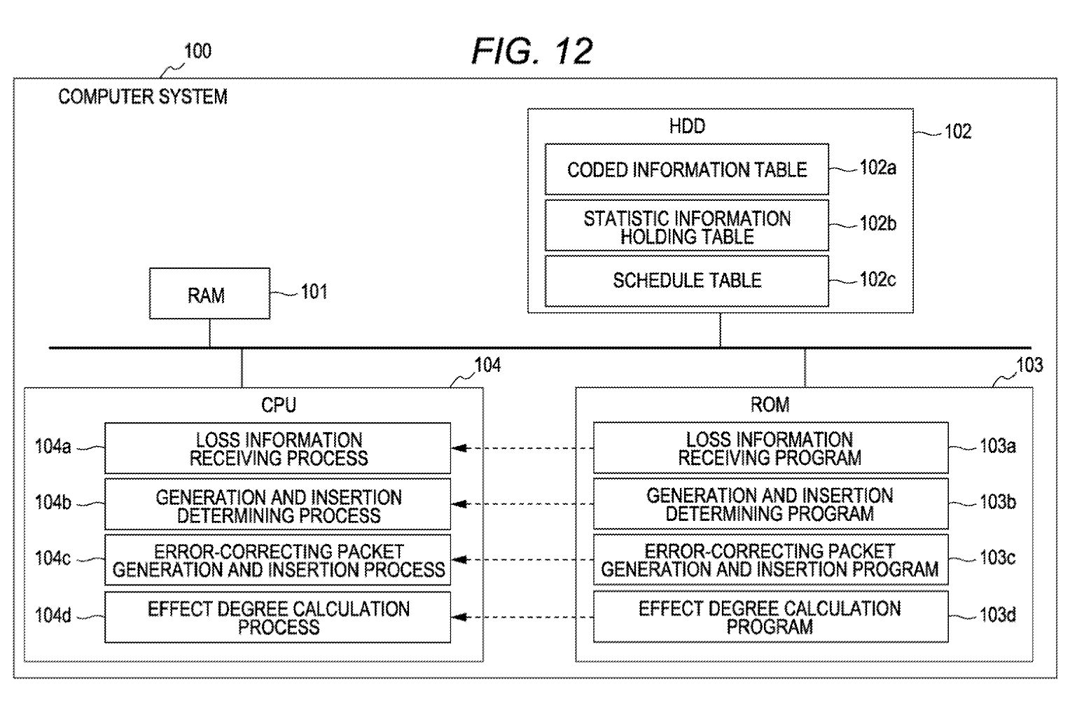

FIG. 12 is a diagram showing an example of the computer system for executing a coding program. As shown in FIG. 12, the computer system 100 includes a RAM 101, an HDD 102, a ROM 103 and a CPU 104. The ROM 103 has stored therein in advance the programs exhibiting the same functions as in the embodiments described above, that is, as shown in FIG. 12, a loss information receiving program 103a, a generation and insertion determining program 103b, an error-correcting packet generation and insertion program 103c and an effect degree calculation program 103d.

The CPU 104, by reading and executing the programs 103a to 103d, determines a loss information receiving process 104a, a generation and insertion determining process 104b, an error-correcting packet generation and insertion process 104c and an effect degree calculation process 104d as shown in FIG. 12. The loss information receiving process 104a corresponds to the communication information receiving unit 11 shown in FIG. 2. Similarly, the generation and insertion determining process 104b corresponds to the error-correcting method determining unit 34, the error-correcting packet generating and insertion process 104c to the error-correcting information generating unit 32, and the effect degree calculation process 104d to the coding processing unit 31 and the error-correcting method determining unit 34, respectively.

The HDD 102 includes a coded information table 102a for storing the received packet loss information, a statistical information holding table 102b for holding the statistical information of the packet loss information from the received packet loss information, and a schedule table 102c for storing the network load information in correspondence with the date/hour. The coded information table 102a and the statistical information holding table 102b correspond to the coded information DB 21 shown in FIG. 2 or 7, and similarly, the schedule table 102c corresponds to the schedule DB 23 shown in FIG. 7.

The programs 103a to 103d are not necessarily stored in the ROM 103, but may be stored in “a portable physical medium” such as a flexible disk (FD), a CD-ROM, an MO disk, an DVD disk, a magneto-optic disk or an IC card inserted in the computer system 100, “a fixed physical medium” such as a hard disk drive (HDD) arranged in or outside the computer system 100, or “another computer system” connected to the computer system 100 through the public line, the internet, a LAN or a WAN, so that the computer system 100 may read the programs from these devices and execute the programs.

The packet loss information including the packet loss restoration rate, the continuous packet loss rate and the packet loss rate of the packets transmitted to the decoding device is received from the decoding device, and based on the packet loss information thus received, the method of generating and inserting an error-correcting redundant packet periodically inserted to restore the lost packet is determined. Based on the error-correcting redundant packet generation and insertion method thus determined, the error-correcting redundant packet is generated and inserted in the packets transmitted to the decoding device. Thus, an appropriate FEC packet generation and insertion method may be selected in accordance with the network situation.

Also, because the error-correcting redundant packet generation and insertion method is determined based on the received packet loss information and the effect degree calculated, the data restoration rate of the decoding device may be improved while at the same time an appropriate FEC packet generation and insertion method may be selected in accordance with the network situation.

For example, by increasing the FEC generation frequency with regard to the part such as a GOP header, an I picture or data the loss of which has a large effect while decreasing the FEC generation frequency for the part the loss of which has a small effect, the quality of the reproduced image can be maintained while suppressing the increase in the transmission rate of the stream as a whole. Also, the error-correcting redundant packet generation and insertion method may be determined based on the received packet loss information and the held statistical information, and therefore, a FEC generation and insertion method capable of reducing or avoiding the packet loss may be selected.

Further, when a quality learning unit for accepting the received packet loss information and determining error-correcting redundant packet generation and insertion method according to the network quality is connected to the network, the selection of a suitable error-correcting redundant packet generation and insertion method may be further based on the quality learning unit. Therefore, a high lost packet restoration rate may be maintained.

Also, by updating the statistical information with the latest information while continuing to adjust the FEC generation method and the FEC insertion frequency even during communication, the environmental change such as an improvement in the network infrastructure can be kept up with. Further, a coding device newly added to the network can determine the FEC generation method and the FEC insertion frequency using the latest loss information.

Further, the error-correcting redundant packet generation and insertion method is determined based on the received packet loss information and the held load information of the transmission date/hour, and therefore, the current FEC generation method and the current FEC insertion frequency may be adjusted while at the same time changing the FEC generation method and the insertion interval before the actual occurrence of the packet loss. Thus, a high lost packet restoration rate may be maintained.

Many features and advantages of the embodiments of the invention are apparent from the detailed specification and, thus, it is intended by the appended claims to cover all such features and advantages of the embodiments that fall within the true spirit and scope thereof. Further, because numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A coding device operable to code original data and transmit the coded data as a plurality of data packets to a destination, the coding device comprising:
a communication unit to receive packet loss information associated with the transmission of at least some of the plurality of data packets, the packet loss information including at least one of a lost packet restoration rate, a continuous packet loss rate and a packet loss rate from the transmission of the at least some of the plurality of data packets; and
an error correction unit to generate and insert an error-correcting redundant packet in subsequent ones of the plurality of data packets for transmission to the destination based on the packet loss information.

2. The coding device according to claim 1, further comprising:
a determination unit to select one of a plurality of predetermined error correction methods to restore a lost packet in the plurality of data packets based on the packet loss information.

3. The coding device according to claim 2, wherein the error correction unit to generate and insert the error-correcting redundant packet in the plurality of data packets based on the selected predetermined error correction method.

4. The coding device according to claim 2, further comprising:
a calculation unit to calculate a degree of effect of each of the plurality of data packets on a decoding of the coded data to generate the original data;
wherein the determination unit is to select one of the plurality of predetermined error correction methods based on the packet loss information and the calculated degree of effect.

5. The coding device according to claim 2, further comprising:
a storage unit to store statistical information of past sets of packet loss information and past network load information that includes a predetermined error correction method correspondingly selected for each of past sets of packet loss information;
wherein the determination unit is to select one of the plurality of predetermined error correction methods based on the packet loss information and the statistical information stored in the storage unit.

6. The coding device according to claim 5, further comprising:
a quality learning unit to update the statistical information stored in the storage unit;
wherein the determination unit is to select one of the plurality of predetermined error correction methods based on the updated statistic information.

7. The coding device according to claim 5, wherein the packet loss information is stored in the coding device in correspondence with a date and hour schedule; and the stored statistical information is stored in accordance with at least one of a day-of-the-week schedule and a month-of-the-year schedule.

8. The coding device according to claim 1, wherein the original data includes video and audio data.

9. A coding method to code original data and transmit the coded data as a plurality of data packets to a destination, the coding method comprising:
receiving packet loss information associated with the transmission of at least some of the plurality of data packets, the packet loss information including a lost packet restoration rate, a continuous packet loss rate and a packet loss rate of the packets transmitted to the decoding device;
selecting one of a plurality of predetermined error correction methods to restore a lost packet in the plurality of data packets based on the packet loss information; and
generating an error-correcting redundant packet and inserting the error-correcting redundant packet in subsequent ones of the plurality of data packets for transmission to the destination based on the selected predetermined error correction method.

10. The coding method according to claim 9, wherein the original data includes video and audio data of a captured image, and the coding method further comprising:
calculating a degree of effect of each of the plurality of data packets on a decoding of the coded data to generate the video and audio data of the captured image.

11. The coding method according to claim 10, wherein selecting one of the plurality of predetermined error correction methods comprising:
selecting one of the plurality of predetermined error correction methods to restore a lost packet in the plurality of data packets based on the calculated degree of effect in addition to the packet loss information.

12. The coding method according to claim 9, further comprising:
storing statistical information of past sets of packet loss information and past network load information that includes a predetermined error correction method correspondingly selected for each of past sets of packet loss information; and
selecting one of the plurality of predetermined error correction methods including selecting one of the plurality of predetermined error correction methods to restore a lost packet in the plurality of data packets based on the stored statistical information in addition to the packet loss information.

13. The coding method according to claim 12, further comprising:
updating the stored statistical information; and
selecting one of the plurality of predetermined error correction methods further includes selecting one of the plurality of predetermined error correction methods to restore a lost packet in the plurality of data packets based on the updated statistical information in addition to the packet loss information.

14. The coding method of claim 1, wherein the packet loss information is stored in the coding device in correspondence with a date and hour schedule.

15. The coding method of claim 12, wherein the stored statistical information is stored in accordance with at least one of a day-of-the-week schedule and a month-of-the-year schedule.

16. The coding method of claim 12, wherein the packet loss information is stored in the coding device in accordance with a first time period; and stored statistical information is stored in accordance with a second time period that is longer than the first time period.

17. A computer-readable medium on which is encoded a coding program to code original data and transmit the coded data as a plurality of data packets to a destination, the coding program to be executed by a computer to at least:
receive packet loss information associated with the transmission of at least some of the plurality of data packets, the packet loss information including a lost packet restoration rate, a continuous packet loss rate and a packet loss rate of the packets transmitted to the decoding device; and
generate an error-correcting redundant packet and inserting the error-correcting redundant packet in subsequent ones of the plurality of data packets for transmission to the destination based on the received packet loss information.
